(19) United States
(12) Patent Application Publication
(10) Pub. No.: US 2024/0169110 A1
(43) Pub. Date: May 23, 2024

(54) CALCULATING, STORING, AND RETRIEVING HIGH-ACCURACY AIRCRAFT PERFORMANCE DATA

(71) Applicant: THE BOEING COMPANY, Chicago, IL (US)

(72) Inventors: Mark D. MCCABE, Larkspur, CO (US); Jeffrey D. POSKIN, Black Diamond, WA (US)

(21) Appl. No.: 17/990,391

(22) Filed: Nov. 18, 2022

(51) Int. Cl. G06F 30/20; G06F 30/15

(52) U.S. Cl. CPC G06F 30/20; G06F 30/15

(57) ABSTRACT

The present disclosure provides for a surrogate model to approximate the results from first principles based models. The surrogate models are configurable to provide any desired degree of accuracy in approximating the first principles models while reducing the computational requirements required to provide the highly precise and accurate results of the first principles model.

Aspects of the present disclosure relate aircraft performance data and providing models for efficient and safe flight planning and operational safety verification using a surrogate model. The surrogate model provides highly accurate performance data and flight planning capabilities without requiring large amounts of computation power and storage.

### BACKGROUND

In general, there are two paradigms for computing aircraft performance for flight operations planning. The first paradigm, known as first principles modeling, is a physics based computational scheme. This computation scheme involves directly solving the airplane performance equations through numerous equations of motion and numerical integration. The first principles modeling produces very accurate results, which are used to maximize airplane operational performance. However, first principles modeling is too computationally intensive for use on board an aircraft (e.g., in the cockpit) or just prior to vehicle/aircraft operations. Other paradigms may be used, but only offer limited or conservative performance data which in turn limits the performance of the vehicle/aircraft in operation. Providing a modeling scheme that provides highly accurate modeling with lower computational requirements remains a challenge.

### SUMMARY

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes a method. The method includes generating a first principles model for vehicle movements, using a first set of inputs for a vehicle configuration, where the first principles model may include a plurality of modeled outputs for the first set of inputs for the vehicle configuration, determining a domain for a surrogate model of the first principles model and generating the surrogate model within the domain to represent the modeled outputs as approximation functions across the domain for the vehicle configuration. The method also includes verifying a fidelity of the surrogate model against the first principles model and installing the surrogate model on a vehicle may include the vehicle configuration. Other embodiments of this aspect include corresponding computer systems, apparatus, and computer programs recorded on one or more computer storage devices, each configured to perform the actions of the methods.

In one aspect, in combination with any example method above or below, the method may also include: determining, from modeling settings for the vehicle configuration, a set of point constraints for a first set of modeling variables and determining, from the modeling settings for the vehicle configuration, a set of region constraints for a second set of modeling variables.

In one aspect, in combination with any example method above or below, where generating the surrogate model may include: generating a tensor-product spline function approximation for each of the modeled outputs using, the domain for the surrogate model, the set of point constraints and the set of region constraints and combining the tensor-product spline function approximations into the surrogate model.

In one aspect, in combination with any example method above or below, where verifying the fidelity of the surrogate model may include: providing one or more test inputs to the surrogate model to generate a surrogate output from the tensor-product spline function approximations across the domain, providing the one or more test inputs to the first principles model to generate a first principles output, comparing the first principles output to the surrogate output, and updating one or more surrogate model parameters based on a fidelity value and the comparison of the first principles output and the surrogate output.

In one aspect, in combination with any example method above or below, where the method may also include: receiving a movement plan request may include a plurality of inputs representing a current condition of the vehicle and field conditions for the vehicle, inputting the plurality of inputs to a first principles engine or to the surrogate model to generate an approved movement plan for the vehicle, and providing the approved movement plan for the vehicle to the vehicle.

In one aspect, in combination with any example method above or below, where generating the approved movement plan for the vehicle utilizes a first amount of computational processing power, and where providing inputs to the surrogate model to generate surrogate model output utilizes a second amount of computational processing power, where the second amount of computational processing power is less than the first amount of computational processing power.

In one aspect, in combination with any example method above or below, where the vehicle may include an aircraft, and where the vehicle configuration may include at least a model for the aircraft and an engine pairing for the aircraft. Implementations of the described techniques may include hardware, a method or process, or computer software on a computer-accessible medium.

One general aspect includes a system. The system includes a processor, a memory storage device including instructions that when executed by the processor enable performance of an operation. The operation may include: generating a first principles model for vehicle movements, using a first set of inputs for a vehicle configuration, where the first principles model may include a plurality of modeled outputs for the first set of inputs for the vehicle configuration, determining a domain for a surrogate model of the first principles model, and generating the surrogate model within the domain to represent the modeled outputs as approximation functions across the domain for the vehicle configuration. The operation also includes verifying a fidelity of the surrogate model against the first principles model and installing the surrogate model on a vehicle may include the vehicle configuration. Other embodiments of this aspect include corresponding computer systems, apparatus, and computer programs recorded on one or more computer storage devices, each configured to perform the actions of the methods.

In one aspect, in combination with any example system above or below, where the operation may further include: determining, from modeling settings for the vehicle configuration, a set of point constraints for a first set of modeling variables and determining, from the modeling settings for the vehicle configuration, a set of region constraints for a second set of modeling variables.

In one aspect, in combination with any example system above or below, where generating the surrogate model may include: generating a tensor-product spline function approximation for each of the modeled outputs using the set of point constraints and the set of region constraints and combining the tensor-product spline function approximations into the surrogate model.

In one aspect, in combination with any example system above or below, where verifying the fidelity of the surrogate model may include: providing one or more test inputs to the surrogate model to generate a surrogate output from the tensor-product spline function approximations across the domain, providing the one or more test inputs to the first principles model to generate a first principles output, comparing the first principles output to the surrogate output, and updating one or more surrogate model parameters based on a fidelity value and the comparison of the first principles output and the surrogate output.

In one aspect, in combination with any example system above or below, where the operation may also include receiving a movement plan request may include a plurality of inputs representing a current condition of the vehicle and field conditions for the vehicle, inputting the plurality of inputs to a first principles engine to generate an approved movement plan for the vehicle, and providing the approved movement plan for the vehicle to the vehicle.

In one aspect, in combination with any example system above or below, where generating the approved movement plan for the vehicle utilizes a first amount of computational processing power, and where providing inputs to the surrogate model to generate surrogate model output utilizes a second amount of computational processing power, where the second amount of processing power is less than the first amount of computational processing power.

In one aspect, in combination with any example system above or below, where the vehicle may include an aircraft, and where the vehicle configuration may include at least a model for the aircraft and an engine pairing for the aircraft. Implementations of the described techniques may include hardware, a method or process, or computer software on a computer-accessible medium.

Another example system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes a method. The method includes receiving, at a vehicle, a surrogate model for vehicle movements for a vehicle configuration, where the surrogate model may include approximation functions for a plurality of modeled outputs and detecting a variation in a movement plan for the vehicle, determining from the surrogate model and the variation in the movement plan a model output. The method also includes updating the movement plan based on the model output. Other embodiments of this aspect include corresponding computer systems, apparatus, and computer programs recorded on one or more computer storage devices, each configured to perform the actions of the methods.

In one aspect, in combination with any example system above or below, where the vehicle may include an aircraft, and where the vehicle configuration may include at least a model for the aircraft and an engine pairing for the aircraft.

In one aspect, in combination with any example system above or below, where detecting the variation in a movement plan for the vehicle may include at least one of: detecting a variation in vehicle conditions compared to an vehicle conditions in an approved movement plan and detecting a variation in field conditions compared to expected field conditions in the approved movement plan.

In one aspect, in combination with any example system above or below, where the field conditions may include at least one of: environmental conditions at a vehicle location, and physical conditions along a route for the vehicle in the movement plan.

In one aspect, in combination with any example system above or below, where the vehicle conditions may include at least one of: current vehicle subsystem status; and payload information.

In one aspect, in combination with any example system above or below, where the approved movement plan is based on first principle calculations performed at the vehicle operations system, and where detecting the variation in a movement plan for the vehicle occurs at a second time subsequent to the first time. Implementations of the described techniques may include hardware, a method or process, or computer software on a computer-accessible medium.

### BRIEF DESCRIPTION OF THE DRAWINGS

So that the manner in which the above recited features can be understood in detail, a more particular description, briefly summarized above, may be had by reference to example aspects, some of which are illustrated in the appended drawings.

FIG. 1 depicts a flight network system, according to aspects of the present disclosure.

FIG. 2 depicts a flight operations system, according to aspects of the present disclosure.

FIG. 3 illustrates a data processing architecture, according to aspects of the present disclosure.

FIGS. 4A-4B illustrate aspects of a surrogate model, according to aspects of the present disclosure.

FIG. 5 is a flowchart of a method generating a surrogate model, according to aspects of the present disclosure.

FIG. 6 is a flowchart of a method utilizing a surrogate model, according to aspects of the present disclosure.

FIG. 7 illustrates a computing device, according to aspects of the present disclosure.

### DETAILED DESCRIPTION

The present disclosure relates to systems and methods for modeling performance data for use in generating, reviewing, and approving vehicle movement plans, such as flight operation plans. While examples described herein relate to aircraft flight operations, the systems and methods described herein may be utilized in a variety of applications, such as operational movement plans of land, rail, or water based vehicles as well as other systems, which utilize operational/movement plans in order to efficiently operate.

Flight operations systems operated by aircraft operators are designed to maximize the efficiency of an overall flight network system (e.g., the efficiency of an airline operators overall operations). For example, a flight operations system will aim to have all available aircraft operate in efficient manner to maximize the use of the aircraft and the benefit to the overall network. To enhance the maximum efficiency of an overall flight system, the flight operations systems also maximize an efficiency of individual aircraft operating under the control of the aircraft operators. For example, a flight operations system will generate or approve vehicle movement plans (flight plans) for an aircraft in order to maximize a given efficiency of the aircraft.

The process of approving flight plans involves many factors including operator specified factors, regulations, and external or environmental conditions. For example, operator specified or regulatory safety factors may limit a proposed flight plan due to the various safety factors and operational capabilities of the aircraft.

In general, flight operations systems utilize the first principles methods described above to review vehicle movement plans within the given constraints. This process often takes place well before the vehicle movement plan is to be implemented and relies on predicted vehicle and environmental conditions. Outputs from first principle methods include performance data which is used to verify the vehicle movement plan as well as provide additional acceptable conditions that the vehicle may operate.

When a vehicle or aircraft experiences changed conditions closer to the implementation of the vehicle movement plan (i.e., close to takeoff), a flight operations system may not have enough time to reevaluate the altered conditions and vehicle movement plan. Currently, in order to maintain efficiency of a flight network system overall (e.g., avoid delays in takeoff), a flight operations system utilizes a second paradigm which offers a faster method to evaluate vehicle movement plans.

This second paradigm, known as second principles modeling, is based on composing table look-ups of a series of low dimensional tables pre-computed and stored on a device, such as a device onboard the vehicle/aircraft. This mathematical architecture, namely approximating the solution to certain equations of motion through a composition of low dimensional functions, does not have granular enough approximation classes to accurately model the desired output. Thus, it is necessary to impose conservative assumptions on this model to ensure that vehicle operations proceed safely.

For example, an aircraft, using a second principles model, may operate below the actual capabilities of the aircraft since the granularity and accuracy of the first principles modeling is not available in the second principles modeling. This method is computationally lightweight, but can reduce operational performance by margins of up to 5%, which costs airplane operators valuable payload and operational efficiency. As noted above, providing a model which has an accuracy of the first principles models with the ease of use and speed of second principles models remains a challenge.

The systems and methods described herein provide for a surrogate model to approximate the results from first principles based models to any desired degree of accuracy while reducing the computational requirements required to provide the highly precise and accurate results of the first principles model. As noted above, although the examples given herein are primarily given in relation to aircraft flight operations, the present disclosure can be used in a variety of environments in which vehicles operate according to movement plans which are subject to various safety and operational requirements.

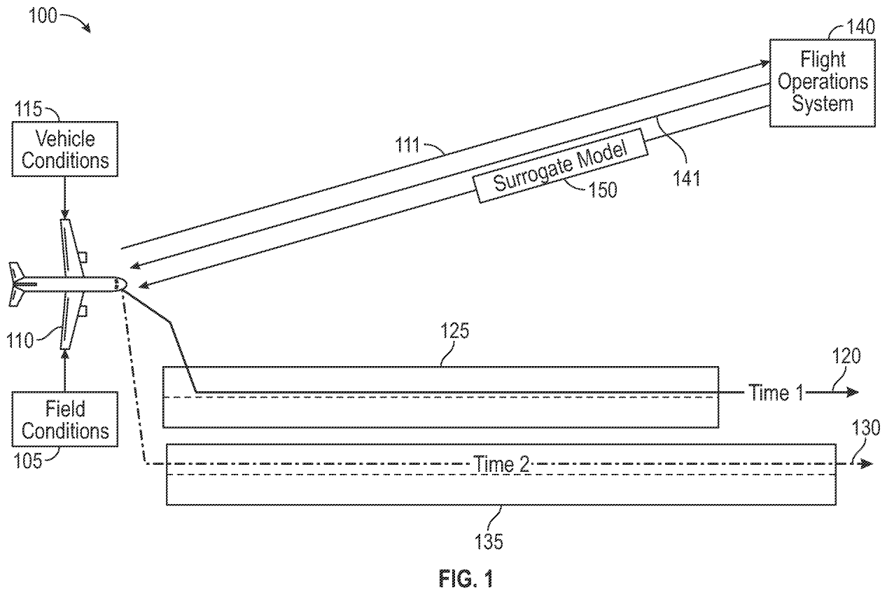

FIG. 1 depicts a flight network system such as system 100, according to aspects of the present disclosure. The system 100 includes an aircraft 110. In some examples, the aircraft 110 is at an airport or airfield prior to commencement of flight operations (e.g., prior to takeoff). The aircraft 110 is in communication with a flight operations system 140 which controls the system 100 including the various other operator aircraft (not shown) that also operate in the system 100. The aircraft 110 is subject to both field conditions 105 and vehicle conditions 115.

Field conditions 105 include a variety of environmental and physical conditions. For example, field conditions 105 include various weather and atmospheric conditions including temperature, humidity, wind speed and direction, precipitation, dew point, etc. for the aircraft or vehicle location. The field conditions 105 also include various information about the physical or geographical space in which the aircraft is present. For example, the field conditions 105 include a current altitude of the aircraft (or airport), available runways such as runway 125 and runway 135 (including corresponding lengths and other related physical properties). The field conditions 105 may also include information regarding information along an entire length of a vehicle movement plan, such as environmental conditions along a flight path and at a destination, delays in the system 100 and/or a general aircraft network under operation of an air traffic management (ATM) system, etc.

The vehicle conditions 115 include a variety of current vehicle conditions and operational capabilities such as vehicle subsystem status. For example, the vehicle conditions 115 may include payload information (e.g., a number passengers or weight of payload), fuel levels, subsystem information (e.g., status of engines, flaps, or other operation systems onboard), etc.

At a time 1 prior to takeoff, the aircraft 110 provides the field conditions 105, vehicle conditions 115 in a request 111 to the flight operations system 140. The request 111 may also include a proposed movement plan for the aircraft 110 (e.g., a proposed takeoff and flight plan for the aircraft) generated at the aircraft 110. For example, the aircraft 110 via systems aboard the aircraft, interactions with a pilot, and interactions with an ATM system, etc. may generate a proposed flight plan for review/approval. In another example, the proposed flight plan may be generated by or present on the flight operations system 140 (e.g., a scheduled flight plan, etc.).

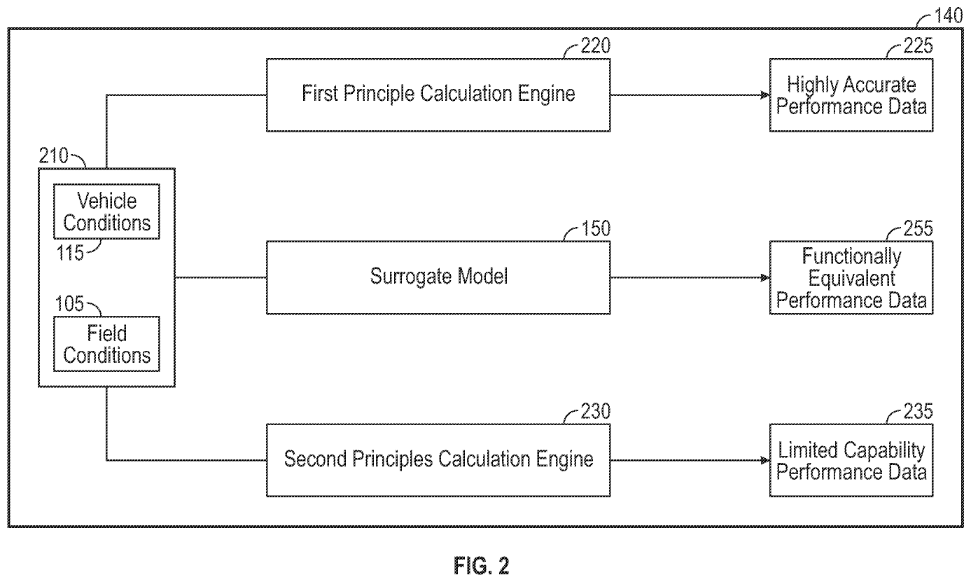

With reference to FIG. 2, which depicts a flight operations system 140, according to aspects of the present disclosure, the flight operations system 140 includes an analysis module 210 which receives the vehicle conditions 115 and field conditions 105 from the aircraft 110 as shown in FIG. 1. The analysis module 210 provides the field conditions 105 and vehicle conditions 115 to a first principles calculation engine 220. As described above, the first principles calculation engine 220 utilizes computationally expensive first principles equations and calculations to generate highly accurate performance data, performance data 225 while using large amounts of computation processing power. In some examples, the performance data 225 includes a required field length, takeoff speeds, climb profile, etc. for the aircraft 110 at the time 1.

In some examples, the analysis module 210 uses the performance data 225 to review and approve or alter the request 111 received from the aircraft 110 and provides an approval 141 to the aircraft 110. Referring back to FIG. 1, at time 1, the flight operations system 140 provides the approval 141 to the aircraft 110 prior to takeoff and the aircraft 110 operates within the requirements received from the flight operations system 140. For example, when the field conditions 105 and vehicle conditions 115 do not change between time 1 and takeoff, the aircraft 110 may utilize a shorter runway, e.g., runway 125, at a first takeoff speed or lower climb profile, etc. along a vehicle movement plan, such as plan 120.

However, in some examples, at a time 2, which is prior to takeoff but does not allow for additional first principle calculations to be performed, the field conditions 105 or vehicle conditions 115 may change. For example, a payload on the aircraft may increase, weather conditions may change, etc. In some examples, minor changes in the conditions may require extensive changes to a flight plan. For example, an increase in ambient temperature may change a required takeoff speed or distance and thus require changes to the flight plan. In this example, the aircraft 110 may resend the conditions in a subsequent request similar to the request 111 to the flight operations system 140 (where a second principles engine in the flight operations system performs second principles calculations) or may utilize a second principles engine aboard the aircraft 110, as described herein.

Referring back to FIG. 2, the analysis module 210 provides the vehicle conditions 115 and field conditions 105 at time 2 to a second principles calculation engine 230 to generate limited capability performance data such as performance data 235. While the second principles calculation engine 230 is computationally efficient and less time consuming, the performance data 235 is less accurate than the performance data 225 and thus the aircraft 110 operates under more conservative or limited conditions. In some examples, the analysis module 210 uses the performance data 235 to review and approve or alter the request 111 received from the aircraft 110 and provides an altered approval 141 to the aircraft 110.

Referring back to FIG. 1, at time 2, the change in field conditions 105 or vehicle conditions 115 and the use of the performance data 235 may require the aircraft operate less efficiently, such as required to use a longer runway 135 or a higher take off speed, etc. along a vehicle movement plan, such as plan 130. In some examples, the aircraft 110 operating along plan 130 is less efficient (e.g., requires more fuel, is limited in payload capacity, limited in aircraft speed, etc.).

In some examples, while the field conditions 105 and vehicle conditions 115 may change at time 2, the aircraft 110 may still be able to operate under the plan 120 or other movement plan that is more efficient than plan 130. For example, while the changed conditions at time may require changes to the plan 120 according to conservative performance data in the performance data 235, the actual performance capabilities of the aircraft 110 may still support operating according to the plan 120.

In order to capture this available capability, the flight operations system 140 and the aircraft 110 utilize a surrogate model 150 generated at the flight operations system 140 and optionally installed on the aircraft 110. The surrogate model 150 may include a model generated using constrained data fitting with tensor-product splines to approximate the results from first principles based models to any desired degree of accuracy while reducing the computational requirements required to provide the highly precise and accurate results of the first principles model. While discussed herein in relation to tensor-product spline functions, the surrogate model may include any class of models including alternative methods for producing a surrogate model for the first principles engine such as Gaussian processes, neural networks, etc.

Referring back to FIG. 2, the analysis module 210 provides the vehicle conditions 115 and field conditions 105 at the time 2 to a surrogate model 150 to generate limited functionally equivalent performance data, such as performance data 255. The performance data 255 provides equivalent performance information to the performance data 225, while requiring less computational resources, (e.g., using less amounts of computational processing power) than the first principles calculation engine 220. In some examples, this analysis can be performed just prior to takeoff while providing accurate performance data.

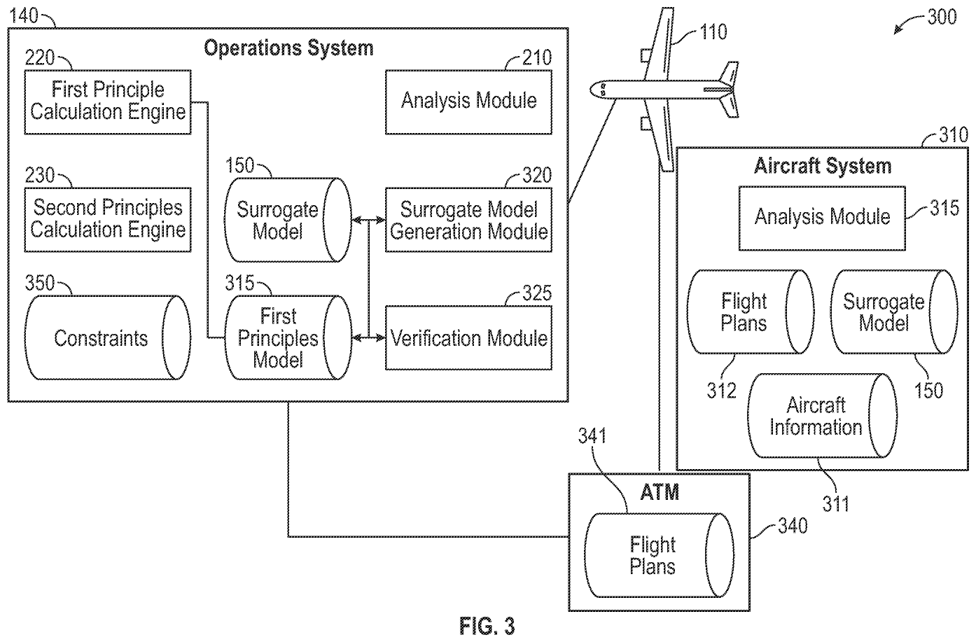

While shown in FIG. 2 as being performed at the flight operations system 140. The model 150 may also be installed on the aircraft 110. For example, an analysis module onboard the aircraft 110 may utilize the installed surrogate model 150 and the conditions at time 2 to generate the performance data 255 onboard the aircraft 110 without requiring further communication with the flight operations system 140. Generation and use of the surrogate model 150 is described in further detail in relation to FIGS. 3-6.

FIG. 3 illustrates a data processing architecture 300, according to aspects of the present disclosure. To verify vehicle movement plans and provide performance data for a vehicle, such as the aircraft 110, the analysis module 210, receives various vehicle movement requests such as flight operations requests (including takeoff authorizations), from the aircraft 110. The analysis module 210 interacts with the first principles calculation engine 220 and provides performance data and/or authorization to the aircraft 110, as well as surrogate model 150 as described in FIGS. 1 and 2.

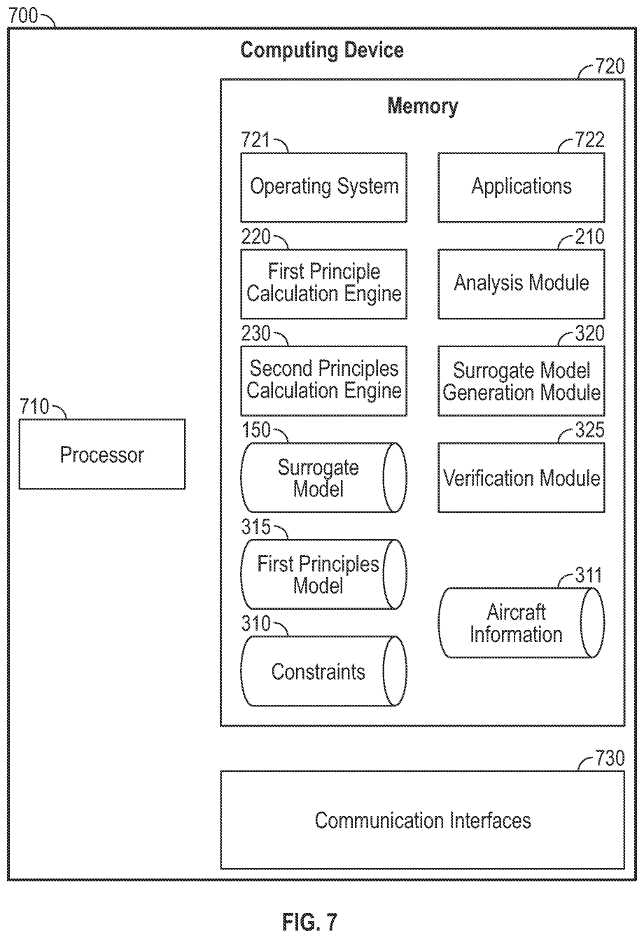

In some examples, the flight operations systems 140 is in communication with the aircraft 110 and an ATM system 340. Each of the aircraft 110, flight operations system 140, and ATM system 340 are representative of or include one or more computing devices, such as those described in relation to FIG. 7, that process and store various data, and operations of the flight operations system 140 or aircraft system 310 may be performed on dedicated hardware or as part of a cloud computing environment in various aspects. Although the aircraft system 310, flight operations system 140, and ATM system 340, are illustrated as single systems, in various aspects, the flight operations system 140 is in communications with several instances of each, and each instance may provide some or all of the associated data in different aspects.

The aircraft 110 (e.g., the aircraft system 310) provides flight operations system 140 with flight plan data 312 and aircraft configuration information, such as aircraft information 311, including conditions of the aircraft and aircraft configurations. The aircraft configurations may include a type of aircraft as well as the engine type installed on the aircraft and other operational information. The flight plan data 312 can at least indicate a base requested flight plan including current planned routes and takeoff information for the aircraft 110.

The ATM system 340, which can include local air traffic controller systems, remote air traffic controller systems as well as regional, national, or global navigation and tracking systems provides flight plan data 341 which may include takeoff data and positional data for aircraft in the controlled airspace of the ATM. In various aspects, the takeoff data includes scheduled times and aircraft queued for takeoff. The positional data can include (ground-related) ADS-B (Automatic Dependent Surveillance—Broadcast) data for where various aircraft are located. The positional data may also include current aircraft positions for the aircraft 110 provided via System Wide Information Management (SWIM). These flight plans may include both requested and assigned flight plans as described herein for the aircraft 110, which includes flight plans filed with air traffic controller systems, as well as clearances for the aircraft 110.

The flight plan data 312 and 341 may also specify information about the aircraft 110 including a number of passengers, a crew manifest (including duty times and “home” airports), departure and estimated time of arrival (ETA) times for a currently scheduled flight, information related to a next scheduled flight, etc., as well as baseline requested flight plans for each of the scheduled flights.

The flight operations system 140 receives the data from the other systems to perform generate and analyze the surrogate model 150, and to communicate the surrogate model and other information back to the various systems for further processing and analysis. For example, the surrogate model 150 for the aircraft 110 is provided back to the aircraft 110 as well as other potential flight implementers.

The flight operations system 140 includes a surrogate model generation module, such as module 320, which uses received aircraft configuration information to generate the surrogate model 150. The verification module 325, verifies that the surrogate model accurately serves as a surrogate model for a first principles model 315.

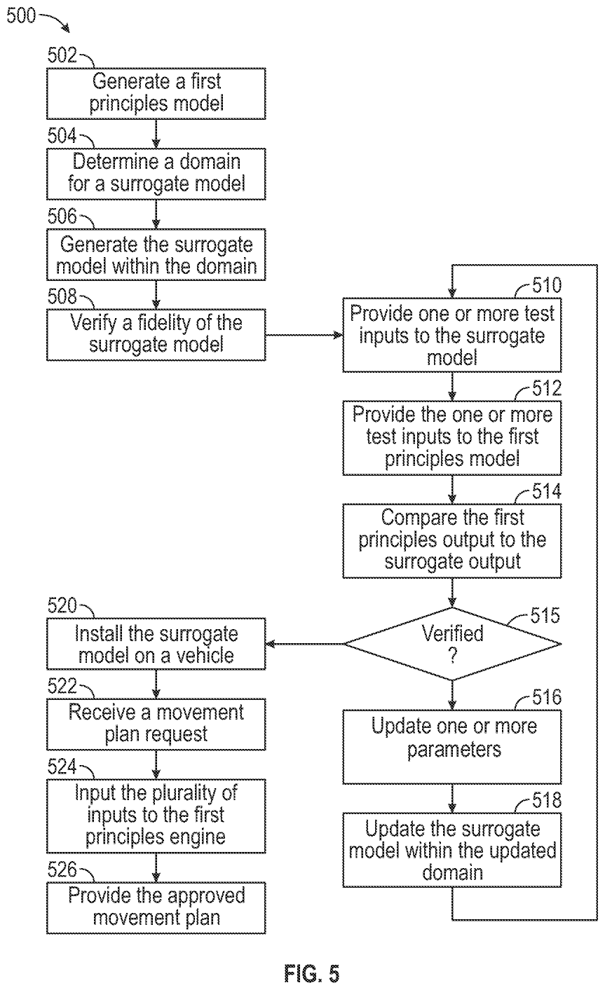

FIG. 5 is a flowchart of a method 500 for generating a surrogate model, according to aspects of the present disclosure. For ease of discussion and illustration, reference will be made to FIGS. 1, 3, and FIGS. 4A-B during the discussion of method 500. Method 500 begins at block 502 where the flight operations system 140 generates a first principles model for vehicle movements, using a first set of inputs for a vehicle configuration, where the first principles model comprises a plurality of modeled outputs for the first set of inputs for the vehicle configuration. For example, the analysis module 210 may cause the first principles calculation engine 220 to generate the first principles model 315 upon receiving aircraft information 311 from the aircraft system 310.

In some examples, the aircraft information 311 includes a type of aircraft and an engine type of the aircraft. For example, the type of aircraft may include the manufacturer and other information related to the build and capabilities of the aircraft 110. Additionally, the aircraft information 311 also includes an engine type installed on the aircraft or other information related to the operational capabilities of the aircraft 110.

In some examples, the aircraft information may be received from an aircraft 110 and aircraft system 310; however, the flight operations system 140 may also generate the first principles model 315 upon receiving user inputted information. For example, when an aircraft operator begins operating a new aircraft configuration (e.g., a new aircraft or new aircraft/engine combination), the aircraft operator may provide the aircraft configuration information to the flight operations system 140 to enable the generation of the first principles model 315 and the model 150.

The first principles model 315 utilizes the aircraft information 311 and constraint information 350 to generate the first principles model 315. Constraint information 350 may include any possible combination of operational parameters for the aircraft that may be used to generate both the first principles model 315 and the model 150. For example, the first principles calculation engine 220 generates the first principles model 315 to represent all or nearly all operational conditions that aircraft may experience, but does not include conditions that aircraft may not experience. For example, ambient temperatures that are not experienced during any expected operation of the aircraft will not be used to generate the first principles model 315. Additionally, payload weight beyond a designed capacity of the aircraft 110 will not be used to generate the first principles model 315. Other constraints and limitation to the first principles model 315 may be determined by the aircraft operator and the flight operations system 140.

In some examples, the first principles model 315 may also be generated piecemeal and iteratively along with the generation of the surrogate model 150 described herein. For example, instead of generating the first principles model 315 for all set of operational parameters, the first principles model 315 is generated according to a specific domain or set of parameters and used to generate a specific portion of the model 150 before iteratively progressing through the generation of the entirety of the model 150.

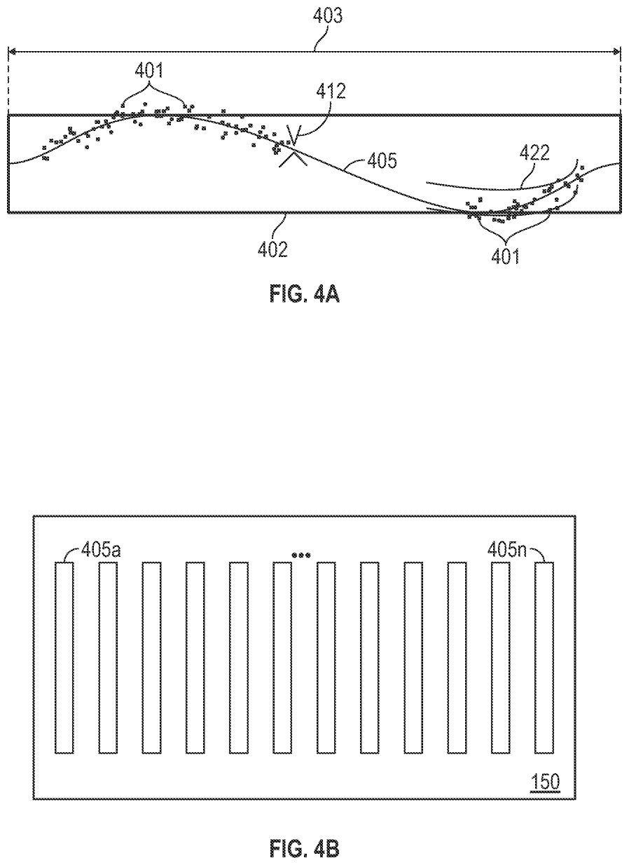

At block 504, the flight operations system 140 determines a domain for a surrogate model of the first principles model. For example, as shown in FIG. 4A, the module 320 may set a domain 403 for a given set of parameters where points 401 represent multivariate scattered data from the first principles model 315, and constraints 402 further define approximation functions, such as a function 405 within the domain 403. In some examples, the domain 403 is a same domain as a domain of the first principle model. That is, the domain 403 is defined by a number of continuous intervals for certain variables (e.g., wind, temperature, or altitude) and a finite set of discrete values for other variables (e.g., flap setting or anti-icing systems, etc.).

In some examples, the surrogate model domain, domain 403, is constrained by the first principles model domain, which is in turn set by aircraft/engine/systems limits, and other practical limitations which are related to a valid range for the source first principles model. For example, an airport elevation is required to be within the range from 1,000 feet below sea level to 15,000 feet above sea level for a particular aircraft and engine pairing or combination, where this range is reflected in the contained values of the domain 403.

The surrogate model domain, domain 403, may be further constrained within the limitations of the first principles source model by operational limitations. For example, a surrogate model for a customer airline may be limited to airport elevations in the range from 1,000 feet below sea level to 7,000 feet above sea level, because the airports served by the customer airline are all within more limited domain.

In some examples, domain 403 is set by a user or by the module 320. In some examples, function 405 is an approximation function such as a tensor-product spline model generated using the points 401 from the first principles model 315 and the constraints 402. In some examples, constraints 402 may include point constraints 412 and/or region constraints 422.

The point constraints 412 may be specified by a finite set of linear functional, which may represent interpolation conditions for the approximation or one of its derivatives, tolerance windows around any data point in points 401, or conservative/one-sided approximations. For example, at a given point of the points 401, there should be no non-negligible differences between the performance calculated by a source first principles model and a constructed surrogate model for conditions with a perfectly flat runway or no wind. For example, a point constraint for a surrogate model may specify/define the behavior of the model at a point in its domain, (e.g. that the accelerate-stop-distance-available on a runway with 0 feet of stopway is equal to the total runway length, among other examples).

The region constraints 422 may be specified by a set of linear functional, parameterized over a compact domain, which may represent: monotonicity or convexity conditions in a given independent variable, global bounds on the approximation or one of its derivatives, or boundary conditions on the approximation. For example, a region constraint controls/defines a behavior of the surrogate model over a full subdomain of a domain. For example, a region constraint may specify that the maximum takeoff weight of a vehicle is monotonically decreasing with respect to the height of an obstacle at a fixed distance from the runway.

In some examples, the module 320 determines, from modeling settings for the vehicle configuration using the constraint information 350, a set of point constraints, such as the point constraints 412 for a first set of modeling variables. The module 320 may also determine, from the modeling settings for the vehicle configuration using constraint information 350, a set of region constraints for a second set of modeling variables, such as the region constraints 422.

At block 506, the flight operations system 140 generates the surrogate model within the domain to represent the modeled outputs as tensor-product splines across the domain for the vehicle configuration. In some examples, the flight operations system 140 generates the surrogate model and the function approximation using a collection of input and output data pairs collected from running the first principles model, such as the plurality of modeled outputs generated at block 502. In some examples, the module 320 generates approximation functions such as a tensor-product spline function approximation, among others. For example, the module 320 generates the function 405 for each of the modeled outputs using the set of point constraints 412 and the set of region constraints 422 and combines the various the tensor-product spline function approximations into the surrogate model. For example, the functions 405a-405n are combined/stored together into the surrogate model 150 shown in FIG. 4B. In this example, the functions 405a-405n may represent various multivariate outputs across the domain specified in the model 150. In some examples, the granularity or degree of accuracy for the models may be set and updated by the user/operator using the various constraints and domain levels.

At block 508, the flight operations system 140 verifies a fidelity of the surrogate model against the first principles model. For example, at block 510, the flight operations system 140 provides one or more test inputs to the surrogate model to generate a surrogate output from the tensor-product splines across the domain and at block at block 512, the flight operations system 140 provides the one or more test inputs to the first principles model to generate a first principles output.

At block 514, the flight operations system 140 compares the first principles output to the surrogate output and at block 515, the flight operations system 140 determines whether the surrogate model is verified based on the comparison of the first principles output and the surrogate output and a fidelity value. In some examples, a fidelity value may include a comparison output. For example, a comparison output may include a maximum takeoff weight for the vehicle given fixed field, ambient, and aircraft conditions. A notional fidelity level/value between these two output values must agree within 0.1%, or other specified percentage, for the surrogate model to be determined to have sufficient quality. In some examples, the fidelity value, including any comparison outputs may apply to several outputs across the surrogate model. When the surrogate model 150 is verified, method 500 proceeds to block 520. However, when the surrogate model requires changes to increase a fidelity of the model, method 500 proceeds to block 516.

At block 516, the flight operations system 140 updates one or more one or more surrogate model parameters. For example, various surrogate model parameters may be updated in order to increase a fidelity of the model 150 to get a closer approximation to the first principles model 315. Example surrogate model parameters may include a set of B-spline coefficients in the case of tensor-product spline approximations, a set of covariance function parameters such length-scales in the case of Gaussian processes, and/or a set of weight and bias parameters in a neural network. At block 518, the flight operations system 140 updates the surrogate model within the updated domain and repeats the steps of blocks 510 to 515 until the surrogate model is effectively representative of the first principles model according to given fidelity.

At block 520, the flight operations system 140 installs the surrogate model on a vehicle comprising the vehicle configuration to provide efficient use of the surrogate model by the vehicle. For example, the flight operations system 140 provides the model 150 to the aircraft 110 and the aircraft system 310 for future use. In some examples, the flight operations system 140 may continue to utilize the first principles engines and/or model to review/approve vehicle movement plans, such as flight plans, as described in relation to FIGS. 1 and 2.

For example, at block 522, the flight operations system 140 receives a movement plan request comprising a plurality of inputs representing a current condition of the vehicle and field conditions for the vehicle. At block 524, the flight operations system 140 inputs the plurality of inputs to a first principles engine or to the surrogate model to generate an approved movement plan for the vehicle. At block 526, the flight operations system 140 provides the approved movement plan for the vehicle to the vehicle. In some examples, generating the approved movement plan for the vehicle utilizes a first amount of computational processing power when using the first principles engine (e.g., the first principles calculation engine 220), In another example, generating the movement plan by providing inputs to the surrogate model 150 to generate a surrogate model output, such as the performance data 255, utilizes a second amount of computational processing power less than the first amount of computational processing power used by the first principles calculation engine 220.

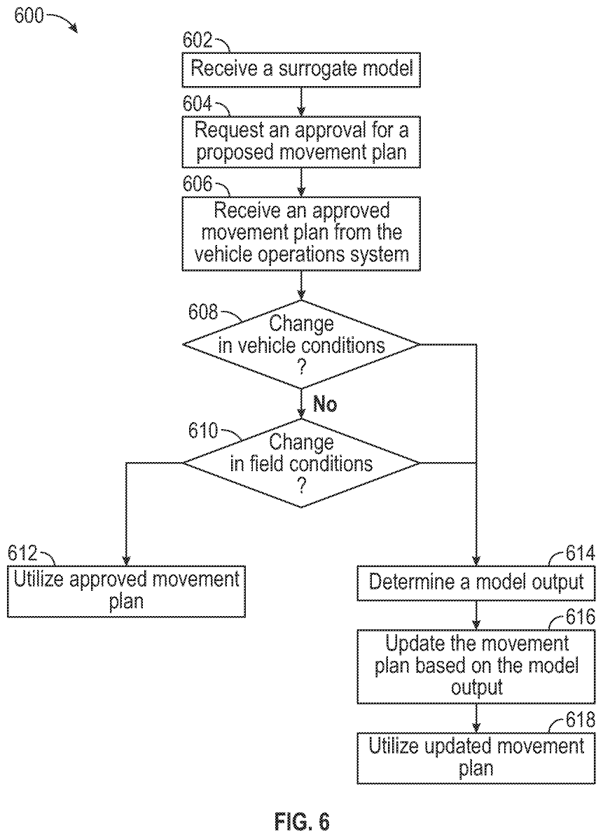

In some examples, as the aircraft 110 is closer to takeoff time, e.g., time 2 in FIG. 1, the aircraft 110 may utilize the surrogate model 150 installed on the aircraft to verify a vehicle movement plan/flight operations as described in method 600 in FIG. 6.

FIG. 6 is a flowchart of a method 600 for using a surrogate model, according to aspects of the present disclosure. Method 600 begins at block 602, where the aircraft system 310 receives a surrogate model, such as the surrogate model 150, for vehicle movements for a vehicle configuration. In some examples, the surrogate model includes tensor-product splines for a plurality of modeled outputs as described in FIGS. 4A-4B.

At block 604, the aircraft system 310 requests, at a first time at the vehicle, such as time 1 in FIG. 1, an approval for a proposed movement plan from a vehicle operations system. At block 606, the aircraft system 310 receives an approved movement plan from the vehicle operations system, where the approved movement plan is based on first principle calculations performed at the vehicle operations system, flight operations system 140.

At blocks 608 and 610, the aircraft system 310 detects a variation in a movement plan for the vehicle at a second time, such as time 2. In some example, the variation in the movement occurs after the aircraft system 310 receives an approved movement plan at block 606. For example, at block 608, the aircraft system 310 detects a variation in vehicle conditions compared to a vehicle conditions in an approved movement plan. For example, variation in the vehicle conditions 115 may include a change in the current vehicle subsystem status (e.g., a change in a subsystem at time 2) or a change in payload information (e.g., a change in a number passengers or weight of a given payload).

Additionally, at block 610, the aircraft system 310 detects a variation in field conditions compared to expected field conditions in the approved movement plan. In some examples, if there is no variation in the conditions, the method 600 proceeds to block 612 where the vehicle/aircraft operates according to the approved movement plan. However, when variations are detected, method 600 proceeds to block 614.

At block 614, the aircraft system 310 determines from the surrogate model and the variation in the movement plan a model output and updates the movement plan based on the model output at block 616. For example, based on the surrogate model 150, the aircraft system 310 may update a takeoff speed, runway length, allowed payload, etc., based on the performance data derived from the surrogate model 150. At block 618 the aircraft system 310 utilizes the updated movement plan during vehicle operations, such as at takeoff and along a given flight plan path. Usage of the surrogate model 150 at the aircraft system 310 allows for efficient aircraft operations without requiring the expensive computations of the first principles calculation engine 220.

FIG. 7 illustrates example computing components of a computing device 700 or other processing system as may be used to provide surrogate modeling as described in the present disclosure by one or more of the flight operations system 140, and/or an onboard computer such as the aircraft system 310 on the aircraft 110.

The computing device 700 includes a processor 710, a memory 720, and an interface 730. The processor 710 and the memory 720 provide computing functionality to run various programs and/or operations for the computing device 700, including the storage and retrieval of the various data described herein.

The processor 710, which may be any computer processor capable of performing the functions described herein, executes commands based on inputs received from a user and the data received from the interface 730.

The interface 730 connects the computing device 700 to external devices, such as, for example, external memory devices, external computing devices, a power source, a wireless transmitter, etc., and may include various connection ports (e.g., Universal Serial Bus (USB), Firewire, Ethernet, coaxial jacks) and cabling. The interface 730 is used to send and receive between computing devices and to communicate alerts (including go, no-go, and caution alerts) to aircraft 110 and the operators thereof.

The memory 720 is a memory storage device that generally includes various processor-executable instructions, that when executed by the processor 710, perform the various functions related to informed de-icing discussed herein. The processor-executable instructions may generally be described or organized into various “applications” or “modules” in the memory 720, although alternate implementations may have different functions and/or combinations of functions. The memory 720 also generally includes data structures that store information for use by or output by the various applications or modules. In the present disclosure, the memory 720 includes at least instructions for an operating system 721 and one or more application(s) 722. The memory 720 may be one or more memory devices, such as, for example, Random Access Memory (RAM), Read Only Memory (ROM), flash memory, or any other type of volatile or non-volatile storage medium that includes instructions that the processor 710 may execute.

When the computing device 700 provides the functionality of the flight operations system 140 (per FIG. 3), the memory 720 includes processor executable instructions to provide the functionalities thereof described in the present disclosure.

In the current disclosure, reference is made to various aspects. However, it should be understood that the present disclosure is not limited to specific described aspects. Instead, any combination of the following features and elements, whether related to different aspects or not, is contemplated to implement and practice the teachings provided herein. Additionally, when elements of the aspects are described in the form of “at least one of A and B,” it will be understood that aspects including element A exclusively, including element B exclusively, and including element A and B are each contemplated. Furthermore, although some aspects may achieve advantages over other possible solutions and/or over the prior art, whether or not a particular advantage is achieved by a given aspect is not limiting of the present disclosure. Thus, the aspects, features, aspects and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

As will be appreciated by one skilled in the art, aspects described herein may be embodied as a system, method or computer program product. Accordingly, aspects may take the form of an entirely hardware aspect, an entirely software aspect (including firmware, resident software, micro-code, etc.) or an aspect combining software and hardware aspects that may all generally be referred to herein as a “circuit,” “module” or “system.” Furthermore, aspects described herein may take the form of a computer program product embodied in one or more computer readable storage medium(s) having computer readable program code embodied thereon.

Program code embodied on a computer readable storage medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described herein with reference to flowchart illustrations and/or block diagrams of methods, apparatuses (systems), and computer program products according to aspects of the present disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the block(s) of the flowchart illustrations and/or block diagrams.

These computer program instructions may also be stored in a computer readable medium that can direct a computer, other programmable data processing apparatus, or other device to function in a particular manner, such that the instructions stored in the computer readable medium produce an article of manufacture including instructions which implement the function/act specified in the block(s) of the flowchart illustrations and/or block diagrams.

The computer program instructions may also be loaded onto a computer, other programmable data processing apparatus, or other device to cause a series of operational steps to be performed on the computer, other programmable apparatus or other device to produce a computer implemented process such that the instructions which execute on the computer, other programmable data processing apparatus, or other device provide processes for implementing the functions/acts specified in the block(s) of the flowchart illustrations and/or block diagrams.

The flowchart illustrations and block diagrams in the Figures illustrate the architecture, functionality, and operation of possible implementations of systems, methods, and computer program products according to various aspects of the present disclosure. In this regard, each block in the flowchart illustrations or block diagrams may represent a module, segment, or portion of code, which comprises one or more executable instructions for implementing the specified logical function(s). It should also be noted that, in some alternative implementations, the functions noted in the block may occur out of the order noted in the Figures. For example, two blocks shown in succession may, in fact, be executed substantially concurrently, or the blocks may sometimes be executed in the reverse order or out of order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

While the foregoing is directed to aspects of the present disclosure, other and further aspects of the disclosure may be devised without departing from the basic scope thereof, and the scope thereof is determined by the claims that follow.

What is claimed is:

1. A method, comprising:
generating a first principles model for vehicle movements, using a first set of inputs for a vehicle configuration, where the first principles model comprises a plurality of modeled outputs for the first set of inputs for the vehicle configuration;
determining a domain for a surrogate model of the first principles model;
generating the surrogate model within the domain to represent the modeled outputs as approximation functions across the domain for the vehicle configuration;
verifying a fidelity of the surrogate model against the first principles model; and
installing the surrogate model on a vehicle comprising the vehicle configuration.

2. The method of claim 1, further comprising:
determining, from modeling settings for the vehicle configuration, a set of point constraints for a first set of modeling variables; and
determining, from the modeling settings for the vehicle configuration, a set of region constraints for a second set of modeling variables.

3. The method of claim 2, wherein generating the surrogate model comprises:
generating a tensor-product spline function approximation for each of the modeled outputs using the domain for the surrogate model, the set of point constraints and the set of region constraints; and
combining the tensor-product spline function approximations into the surrogate model.

4. The method of claim 3, wherein verifying the fidelity of the surrogate model comprises:
providing one or more test inputs to the surrogate model to generate a surrogate output from the tensor-product spline function approximations across the domain;
providing the one or more test inputs to the first principles model to generate a first principles output;
comparing the first principles output to the surrogate output; and
updating one or more surrogate model parameters based on a fidelity value and the comparison of the first principles output and the surrogate output.

5. The method of claim 1, further comprising:
receiving a movement plan request comprising a plurality of inputs representing a current condition of the vehicle and field conditions for the vehicle;
inputting the plurality of inputs to a first principles engine or to the surrogate model to generate an approved movement plan for the vehicle; and
providing the approved movement plan for the vehicle to the vehicle.

6. The method of claim 5, wherein generating the approved movement plan for the vehicle utilizes a first amount of computational processing power, and wherein providing inputs to the surrogate model to generate surrogate model output utilizes a second amount of computational processing power, wherein the second amount of computational processing power is less than the first amount of computational processing power.

7. The method claim 1, wherein the vehicle comprises an aircraft, and wherein the vehicle configuration comprises at least a model for the aircraft and an engine pairing for the aircraft.

8. A system, comprising:
a processor;
a memory storage device including instructions that when executed by the processor enable performance of an operation comprising:
generating a first principles model for vehicle movements, using a first set of inputs for a vehicle configuration, where the first principles model comprises a plurality of modeled outputs for the first set of inputs for the vehicle configuration;
determining a domain for a surrogate model of the first principles model;
generating the surrogate model within the domain to represent the modeled outputs as approximation functions across the domain for the vehicle configuration;
verifying a fidelity of the surrogate model against the first principles model; and
installing the surrogate model on a vehicle comprising the vehicle configuration.

9. The system of claim 8, wherein the operation further comprises:
determining, from modeling settings for the vehicle configuration, a set of point constraints for a first set of modeling variables; and
determining, from the modeling settings for the vehicle configuration, a set of region constraints for a second set of modeling variables.

10. The system of claim 9, wherein generating the surrogate model comprises:
generating a tensor-product spline function approximation for each of the modeled outputs using the set of point constraints and the set of region constraints; and
combining the tensor-product spline function approximations into the surrogate model.

11. The system of claim 10, wherein verifying the fidelity of the surrogate model comprises:
providing one or more test inputs to the surrogate model to generate a surrogate output from the tensor-product spline function approximations across the domain;
providing the one or more test inputs to the first principles model to generate a first principles output;
comparing the first principles output to the surrogate output; and
updating one or more surrogate model parameters based on a fidelity value and the comparison of the first principles output and the surrogate output.

12. The system of claim 8, further comprising:
receiving a movement plan request comprising a plurality of inputs representing a current condition of the vehicle and field conditions for the vehicle;
inputting the plurality of inputs to a first principles engine to generate an approved movement plan for the vehicle; and
providing the approved movement plan for the vehicle to the vehicle.

13. The system of claim 12, wherein generating the approved movement plan for the vehicle utilizes a first amount of computational processing power, and wherein providing inputs to the surrogate model to generate surrogate model output utilizes a second amount of computational processing power, wherein the second amount of processing power is less than the first amount of computational processing power.

14. The system of claim 8, wherein the vehicle comprises an aircraft, and wherein the vehicle configuration comprises at least a model for the aircraft and an engine pairing for the aircraft.

15. A method comprising:
receiving, at a vehicle, a surrogate model for vehicle movements for a vehicle configuration, where the surrogate model comprises approximation functions for a plurality of modeled outputs;
detecting a variation in a movement plan for the vehicle;
determining from the surrogate model and the variation in the movement plan a model output; and
updating the movement plan based on the model output.

16. The method of claim 15, wherein the vehicle comprises an aircraft, and wherein the vehicle configuration comprises at least a model for the aircraft and an engine pairing for the aircraft.

17. The method of claim 15, wherein detecting the variation in a movement plan for the vehicle comprises at least one of:
detecting a variation in vehicle conditions compared to a vehicle conditions in an approved movement plan; and
detecting a variation in field conditions compared to expected field conditions in the approved movement plan.

18. The method of claim 17, wherein the field conditions comprise at least one of:
environmental conditions at a vehicle location; and
physical conditions along a route for the vehicle in the movement plan.

19. The method of claim 17, wherein the vehicle conditions comprise at least one of:
current vehicle subsystem status; and
payload information.

20. The method of claim 15, further comprising:
requesting, at a first time at the vehicle, an approval for a proposed movement plan from a vehicle operations system; and
receiving an approved movement plan from the vehicle operations system, wherein the approved movement plan is based on first principle calculations performed at the vehicle operations system, and wherein detecting the variation in a movement plan for the vehicle occurs at a second time subsequent to the first time.
